(19) United States
(12) Patent Application Publication
(10) Pub. No.: US 2026/0190980 A1
(43) Pub. Date: Jul. 2, 2026

(54) BONDED DEVICE STRUCTURES INCLUDING SLOTTED REDISTRIBUTION LAYER PADS AND METHODS OF FABRICATION THEREOF

(71) Applicant: Taiwan Semiconductor Manufacturing Company Limited, Hsinchu (TW)

(72) Inventors: Yi-Fen TSAI, Hsinchu (TW); Chen-Shien CHEN, Zhubei City (TW); Yinlung LU, Hsinchu (TW); Yao-Chun CHUANG, Hsinchu City (TW); Tien-Chung YANG, Hsinchu City (TW); Wei-Hao CHEN, New Taipei City (TW); Hsu-Hsien CHEN, Hsinchu City (TW)

(21) Appl. No.: 19/007,783

(22) Filed: Jan. 2, 2025

(51) Int. Cl. H01L 23/528; H01L 21/768; H01L 23/00; H01L 25/065

(52) U.S. Cl. CPC H10W 20/435; H10W 20/056; H10W 20/089; H10W 20/092; H10W 20/43; H10W 70/05; H10W 70/60; H10W 70/65; H10W 80/312; H10W 80/327; H10W 90/00; H10W 90/792

(57) ABSTRACT

Bonded device structures and methods of fabrication thereof that provide improved uniformity of redistribution layer (RDL) pad surfaces. The RDL pads are formed by depositing (e.g., electroplating) a metal material on a semiconductor device structure, and performing a planarization process to provide discrete RDL pads having uniform, substantially flat upper surfaces with minimal differences in surface elevation. Passivation layer(s) and a bonding layer are formed over RDL pads, and bonding pad vias contact the upper surfaces of the RDL pads. In some embodiments, the flatness of the RDL pads may be enhanced by providing dielectric-filled slots filled in at least some of the RDL pads and/or non-functional “dummy” RDL pads between functional RDL pads to mitigate non-uniformities during the planarization process. Improved uniformity and flatness of the RDL pads may enhance the reliability and performance of bonded device structures.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional (3D) devices provide improved integration density and other advantages because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view illustrating a first device structure according to various embodiments of the present disclosure.

FIG. 2 is a vertical cross-sectional view illustrating the first device structure including a first dielectric layer formed over the upper surface of a first interconnect structure 105 according to various embodiments of the present disclosure.

FIG. 3 is a vertical cross-sectional view illustrating the first device structure including a patterned mask over the first dielectric layer according to various embodiments of the present disclosure.

FIG. 4 is a vertical cross-section view of the first device structure following an etching process that removes portions of the first dielectric layer and the dielectric material of the first interconnect structure according to various embodiments of the present disclosure.

FIG. 5 a vertical cross-sectional view illustrating the first device structure including a patterned mask over the first dielectric layer according to various embodiments of the present disclosure.

FIG. 6 is a vertical cross-section view of the first device structure following an etching process that forms trench portions the first dielectric layer according to various embodiments of the present disclosure.

FIG. 7 a vertical cross-sectional view illustrating the first device structure including a metal material within the first and second via openings and the first and second trench openings and over the upper surface of the first dielectric layer according to various embodiments of the present disclosure.

FIG. 8 a vertical cross-sectional view illustrating the first device structure including a patterned mask over the metal material according to various embodiments of the present disclosure.

FIG. 9 is a vertical cross-section view of the first device structure following an etching process that forms openings in the metal material according to various embodiments of the present disclosure.

FIG. 10 a vertical cross-sectional view illustrating the first device structure including a dielectric fill material over the metal material and within the openings in the metal material according to various embodiments of the present disclosure.

FIG. 11 is a vertical cross-section view of the first device structure following a planarization process that removes the metal material and the dielectric fill material from over the upper surface of the first dielectric layer according to various embodiments of the present disclosure.

FIG. 12 is a vertical cross-section view of the first device structure illustrating a second dielectric layer over the upper surface of the first dielectric layer, the upper surface of a first redistribution layer (RDL) pad, and the upper surface of a second RDL pad according to various embodiments of the present disclosure.

FIG. 13 is a vertical cross-section view of the first device structure illustrating a third dielectric layer over the second dielectric layer according to various embodiments of the present disclosure.

FIG. 14 is a vertical cross-section view of the first device structure illustrating a first bonding layer over the third dielectric layer according to various embodiments of the present disclosure.

FIG. 15 is a vertical cross-section view of the first device structure illustrating bonding pads formed within the first bonding layer and bonding pad vias (BPVs) extending between the bonding pads and the RDL pads according to various embodiments of the present disclosure.

FIG. 16 is a vertical cross-section view illustrating the first device structure bonded to a second device structure to form a bonded device structure according to various embodiments of the present disclosure.

FIG. 17 a vertical cross-sectional view illustrating a first device structure including a patterned mask over the first dielectric layer according to other various embodiments of the present disclosure.

FIG. 18 is a vertical cross-section view of the first device structure following an etching process that forms trench portions in the first dielectric layer according to other various embodiments of the present disclosure.

FIG. 19 a vertical cross-sectional view illustrating the first device structure including a metal material within the first and second via openings and first, second and third trench openings, and over the upper surface of the first dielectric layer according to other various embodiments of the present disclosure.

FIG. 20 is a vertical cross-section view of the first device structure including openings in the metal material according to other various embodiments of the present disclosure.

FIG. 21 a vertical cross-sectional view illustrating the first device structure including a dielectric fill material over the metal material and within the openings in the metal material according to other various embodiments of the present disclosure.

FIG. 22 is a vertical cross-section view of the first device structure following a planarization process that removes the metal material and the dielectric fill material from over the upper surface of the first dielectric layer to provide first, second, and third RDL pads according to other various embodiments of the present disclosure.

FIG. 23A is a top view of a portion of a first device structure following a planarization process according to an embodiment of the present disclosure.

FIG. 23B is a vertical cross-section view of the portion of a first device structure taken along line A-A′ in FIG. 23A.

FIG. 24 is a vertical cross-section view of the portion of the first device structure of FIGS. 23A-23B following the formation of passivation layers over the RDL layers, a first bonding layer over the passivation layers, and BPVs extending through the first bonding layer and the passivation layers and contacting the first RDL pad and the second RDL pad according to various embodiments of the present disclosure.

FIG. 25 is a flowchart illustrating a method of fabricating a semiconductor structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and specifically to bonded device structures that include a plurality of semiconductor integrated circuit (IC) structures bonded to one another. The bonded device structures may be in a configuration such as a system on integrated chip (SoIC), chip on wafer on substrate (CoWoS®), chip on wafer (CoW), etc. Such bonded device structures may increase the density of devices that may occupy a given planar area or “footprint.”

Semiconductor integrated circuits may include a semiconductor material substrate, such as a silicon substrate, having a number of circuit components and elements formed on and/or within the semiconductor material. Semiconductor integrated circuits are typically fabricated by sequentially depositing insulating or dielectric layers, conductive layers, and semiconductive layers of material over the semiconductor substrate (e.g., a wafer), and patterning the various material layers using lithography to form integrated circuits.

A bonded device structure may be formed by placing a second device structure (e.g., a semiconductor wafer or die) onto first device structure (e.g., a separate semiconductor wafer or die). A bonding process may be used to bond bonding features on the first device structure to corresponding bonding features on the second device structure. In some embodiments, a direct bonding technique, such as metal-to-metal (M-M) and dielectric-to-dielectric (D-D) bonding techniques, may be used to bond the device structures to form the bonded device structure. In such bonding techniques, bonding layers including an array of metal bonding pads surrounded by a dielectric material may be formed on the structures to be bonded. The bonding layer on the second device structure may be aligned over the corresponding bonding layer on the first device structure, and the two bonding layers may be brought into contact with one another. This may result in a chemical pre-bond between the dielectric material of the respective bonding layers. An annealing process may then be performed to promote bonding of the metal bonding pads of the respective bonding layers, thereby producing metal bonds extending between the first device structure and the second device structure. Other types of bonding processes, such as a fusion bonding process between dielectric bonding material layers, may also be utilized.

In a direct bonding technique as described above, redistribution layer (RDL) pads may be formed over the semiconductor integrated circuits of the device structures and may be electrically coupled to underlying interconnect structures of the semiconductor integrated circuits by redistribution layer vias (RVs). One or more passivation layers may be formed over the RDL pads, and a bonding layer including an array of metal bonding pads surrounded by a dielectric material may be formed over the passivation layer(s). Bonding pad vias (BPV) may be formed through the passivation layer(s) to electrically couple the bonding pads of the bonding layer to the RDL pads.

In some cases, the RDL pads may include AlCu material formed using a physical deposition process, such as sputtering. Recently, there has been a transition towards forming copper RDL pads via electrochemical deposition, such as electroplating or “ECP,” which may help to meet the requirements of advanced packaging designs. The copper (Cu) materials used in the pads may provide pads with improved resistance characteristics. However, it has been found that the surface morphology of RDL pads formed by ECP may have a significant effect on the reliability and performance of bonded device structures. For example, differences in surface elevation and/or surface roughness of the RDL pads may produce reliability issues, including increases in surface resistance, skin effect and/or EM effect. This may be due in part to the susceptibility of copper versus AlCu materials to corrosion. In addition, contacting BPVs on non-uniform RDL pad surfaces may also lead to reliability issues, such as over-etching, metal (e.g., Cu) loss and other defects after subsequent thermal processing.

Various embodiments disclosed herein are directed to bonded device structures and methods of fabrication thereof that provide improved uniformity of RDL pad surfaces that may enhance the reliability and performance of the bonded device structures. In various embodiments, the RDL pads may be formed by forming a metal material over the interconnect structure of a semiconductor device structure via a suitable deposition process, such as electroplating, and performing a planarization process, such as a chemical mechanical planarization (CMP) process to provide discrete RDL pads having uniform, substantially flat upper surfaces with minimal differences in surface elevation. One or more passivation layers may be formed over the planarized surfaces of the RDL pads, and a bonding layer may be formed over the one or more passivation layer(s). Bonding pad vias (BPVs) may be formed contacting the upper surfaces of the RDL pads and electrically connecting the RDL pads to bonding pads of the bonding layer. The bonding layer may be used to bond the semiconductor device structure to an additional semiconductor device structure to provide a bonded device structure.

In some embodiments, the flatness of the surfaces of the RDL pads may be enhanced by providing slots filled with a dielectric material in at least some of the RDL pads, such as RDL pads having relatively larger surface areas. The slots may mitigate the effects of erosion and dishing during the planarization process by providing a more uniform ratio of metal to dielectric material in contact with the polishing pad during the planarization process. This may mitigate against dishing and/or erosion effects and provide a flatter upper surface of the RDL pads. Alternatively, or in addition, one or more non-functional, or “dummy” RDL pads that do not provide an electrical pathway between the bonding layer and the interconnect structure in the finished semiconductor device structure may be provided between functional RDL pads that do provide electrical connections between the bonding layer and the interconnect structure in the finished semiconductor device structure. The presence of one or more “dummy” RDL pads may similarly mitigate non-uniformities during the planarization process by providing a more uniform ratio of metal to dielectric material in contact with the polishing pad during the planarization process.

In various embodiments, by minimizing elevation differences and reducing surface roughness of the RDL pads, surface resistance and other conduction effects may be reduced, and consistent and precise landing regions for the BPVs may be provided, which may enhance the reliability and performance of the bonded device structures.

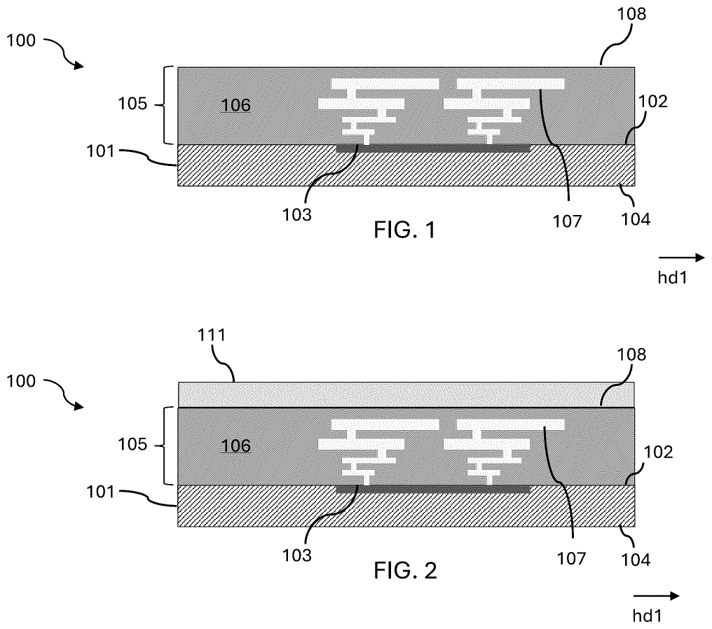

FIGS. 1-16 are sequential vertical cross-sectional views illustrating intermediate structures that may be formed during a process of fabricating a bonded device structure according to various embodiments of the present disclosure. FIG. 1 is a vertical cross-sectional view illustrating a first device structure 100 according to various embodiments of the present disclosure. The first device structure 100 may include a first semiconductor substrate 101 (e.g., a semiconductor wafer) that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the first semiconductor substrate 101 may be a semiconductor-on-insulator (SOI) substrate.

The first semiconductor substrate 101 may include a first major surface (i.e., a front side surface 102) and a second major surface (i.e., a backside surface 104). In some embodiments, a thickness of the first semiconductor substrate 101 between the front side surface 102 and the backside surface 104 may be between about 100μm and about 800 μm, although a first semiconductor substrate 101 having a greater or lesser thickness may also be utilized. In some embodiments, one or more through-substrate vias (TSVs) (not shown in FIG. 1) may be formed through the first semiconductor substrate 101 to provide an electrical connection between the backside surface 104 and the front side surface 102 of the first semiconductor substrate 101.

In some embodiments, a plurality of devices 103 may be disposed on, over and/or in the front side surface 102 of the first semiconductor substrate 101. The devices may include, for example, active devices, passive devices, or a combination thereof. In some embodiments, the plurality of devices 103 disposed on, over and/or in the front side surface 102 of the first semiconductor substrate 101 may include integrated circuit devices. The integrated circuit devices may include, for example, transistors (e.g., field-effect transistors (FETs)), capacitors, resistors, diodes, photodiodes, fuse devices, or other similar devices. In some embodiments, the integrated circuit devices may include gate electrodes, source/drain regions, spacers, isolation trenches, and the like.

The first device structure 100 may additionally include a first interconnect structure 105 over the front side surface 102 of the first semiconductor substrate 101. The first interconnect structure 105 (which may also be referred to as a first redistribution layer (RDL)) may include metal features 107 (e.g., metal lines, vias, etc.) formed within a dielectric material 106 (e.g., one or more inter-layer dielectric (ILD) layers and/or inter-metal dielectric (IMD) layers) that may provide connections to and/or between various devices 103 located on, over and/or in the front side surface 102 of the first semiconductor substrate 101. The dielectric material 106 of the first interconnect structure 106 may include a suitable dielectric material, such as silicon oxide, silicon nitride, silicon carbide, silicon oxynitride, silicon carbon nitride, a low-K dielectric material, and extremely low-K (ELK) dielectric material, undoped silicon glass (USG), fluorosilicate glass (FSG), phosphor-silicate glass (PSG), etc., including combinations thereof. Other suitable dielectric materials for the dielectric material 106 are within the contemplated scope of disclosure. In some embodiments, the dielectric material 106 may include a suitable passivation material, such as silicon nitride, undoped silicon glass, silicon oxide, carbon-doped silicon dioxide, and the like, located over the metal features 107 and forming the upper surface 108 of the first interconnect structure 105.

In some embodiments, the first device structure 100 may include a semiconductor wafer. The semiconductor wafer may include multiple instances of integrated circuit structures, each including a plurality of devices 103 and an interconnect structure 105 as shown FIG. 1, formed on a common semiconductor substrate 101. A dicing process may be subsequently performed to separate individual dies from the wafer (i.e., singulate), where each die may include a portion of the semiconductor substate 101 having an integrated circuit structure formed thereon. In other embodiments, the first device structure 100 may include a semiconductor die that has been separated from a semiconductor wafer (e.g., via an above-described dicing process).

FIG. 2 is a vertical cross-sectional view illustrating the first device structure 100 including a first dielectric layer 111 formed over the upper surface 108 of the first interconnect structure 105 according to various embodiments of the present disclosure. Referring to FIG. 2, a first dielectric layer 111 may be deposited over the upper surface 108 of the dielectric material 106 of the first interconnect structure 105. The first dielectric layer 111 may include a suitable dielectric material. In some embodiments, the first dielectric layer 111 may include an inorganic dielectric material with low dielectric constant, such as undoped silicon glass, silicon nitride, silicon oxide, carbon-doped silicon dioxide, etc. Other suitable materials for the first dielectric layer 111 are within the contemplated scope of disclosure. In various embodiments, the first dielectric layer 111 may be deposited using any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like, including various combinations thereof.

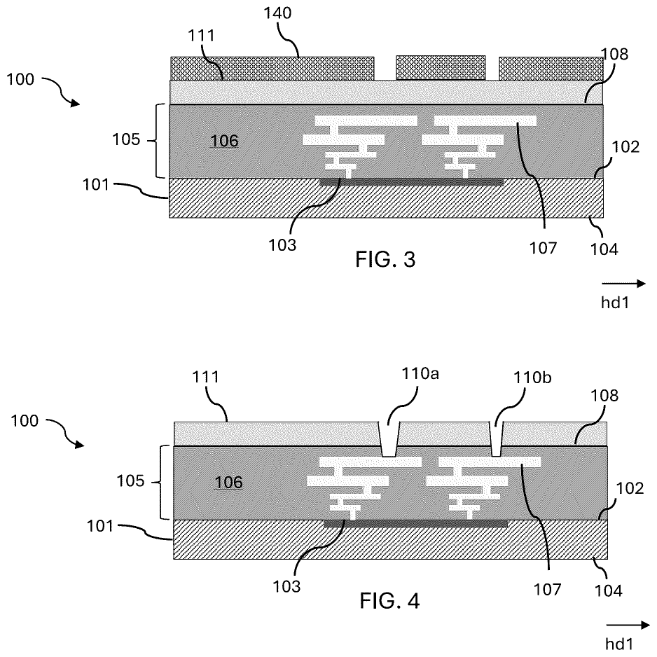

FIG. 3 is a vertical cross-sectional view illustrating the first device structure 100 including a patterned mask 140 over the first dielectric layer 111 according to various embodiments of the present disclosure. Referring to FIG. 3, a mask 140 may be formed as a continuous layer of material over the upper surface of the first dielectric layer 111. In various embodiments the mask 140 may include a layer of photosensitive material, such as a photoresist material. The mask 140 may be deposited using a suitable process, such as via a spin coating process. The mask 140 may be patterned using photolithographic techniques to form a plurality of openings through the mask 140. In various embodiments, the openings may be formed by exposing select portions of the mask 140 to radiation (e.g., UV radiation) through a lithographic mask (i.e., a photomask), where the photosensitive material of the mask 140 may be altered when exposed to certain types of radiation. For example, the mask 140 may include a positive photoresist material, in which exposure to ultraviolet (UV) radiation makes polymers contained in the photoresist material more soluble and easier to remove, or a negative photoresist material, in which exposure to UV radiation makes the polymers crosslink and harder to remove. Exposing the mask 140 to radiation through the lithographic mask may transfer the lithographic mask pattern to the mask 140. A developing process may then be utilized to remove the more soluble regions of the mask 140 (e.g., using a developer solution) and provide a patterned mask 140 including openings through the mask 140 as shown in FIG. 3. The upper surface of the first dielectric material 111 may be exposed at the bottom of the openings through the mask 140. In some embodiments, the location of each of the openings in the mask 140 may correspond to the location of a redistribution layer via (RV) to be subsequently formed as described in further details below. In some embodiments, the openings through the mask 140 may have non-uniform sizes or shapes. For example, one or more of the openings through the mask 140 may have a larger horizontal cross-sectional area compared to other opening(s) through the mask 140.

FIG. 4 is a vertical cross-section view of the first device structure 100 following an etching process that removes portions of the first dielectric layer 111 and the dielectric material 106 of the first interconnect structure 105 according to various embodiments of the present disclosure. Referring to FIG. 4, an etching process may be performed through the patterned mask 140 to remove portions of the first dielectric layer 111 and the dielectric material 106 of the first interconnect structure 105 that are exposed through the openings in the patterned mask 140 to provide a plurality of via openings 110a and 110b extending through the first dielectric layer 111 and into the dielectric material 106 of the first interconnect structure 105. A metal feature 107 (e.g., a “top metal” feature) of the first interconnect structure 105 may be exposed at the bottom of each of the via openings 110a and 110b. The embodiment of FIG. 4 illustrates a pair of via openings, including a first via opening 110a and a second via opening 110b. The first via opening 110a has a greater horizontal width than the second via opening 110b. Following the etching process, the patterned mask 140 may be removed via a suitable process, such as by ashing or by dissolution using a solvent.

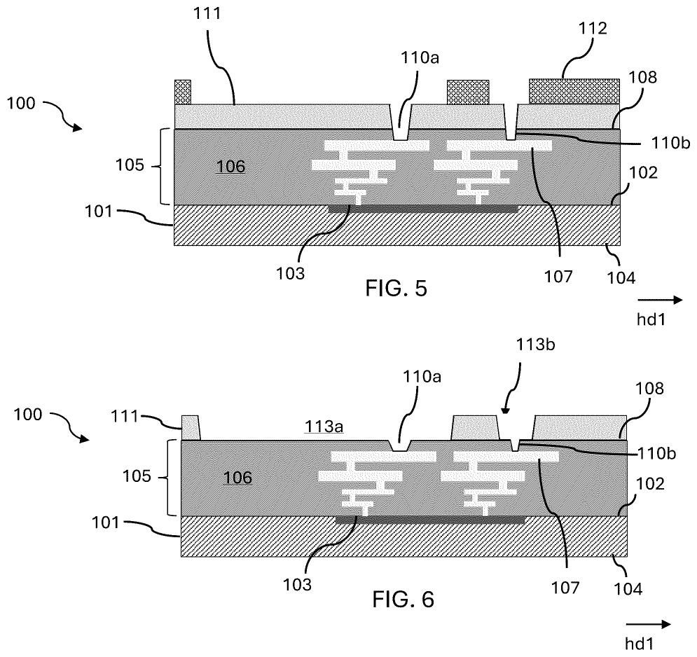

FIG. 5 a vertical cross-sectional view illustrating the first device structure 100 including a patterned mask 112 over the first dielectric layer 111 according to various embodiments of the present disclosure. Referring to FIG. 5, a patterned mask 112 may be formed over the upper surface of the first dielectric layer 111. The patterned mask 112 may be formed by depositing continuous layer of photosensitive material (e.g., photoresist) over the upper surface of the first dielectric layer 111 and patterning the continuous layer of photosensitive material using photolithographic techniques to form a plurality of openings through the mask 112, as described above with reference to FIG. 2. In various embodiments, one or more via openings 110a, 110b may be exposed in at least a portion of the openings through the mask 112. The openings through the mask 112 may have non-uniform shapes and/or sizes. In the embodiment of FIG. 5, for example, the opening in which the first via opening 110a is exposed has a larger width dimension along at least a first horizontal direction hd1 than the opening in which the second via opening 110b is exposed.

FIG. 6 is a vertical cross-section view of the first device structure 100 following an etching process that forms trench openings 113a, 113b the first dielectric layer 111 according to various embodiments of the present disclosure. Referring to FIG. 6, an etching process may be performed through the patterned mask 112 to remove portions of the first dielectric layer 111 that are exposed through the openings in the patterned mask 112 to provide a plurality of trench openings 113a, 113b extending through the first dielectric layer 111. The etching process may stop at the dielectric material 106 of the first interconnect structure 105 such that the dielectric material 106 may be exposed at the bottom of the trench openings 113a, 113b. The via openings 110a, 110b may each further extend from the bottom of a trench opening 113a, 113b through the dielectric material 106 of the first interconnect structure 105 to a top metal feature 107 of the first interconnect structure 105. The embodiment of FIG. 6 illustrates a pair of trench openings, including a first trench opening 113a and a second trench opening 113b. The first via opening 110a may be located within and is continuous with the first trench opening 113a, and the second via opening 110b is located within and is continuous with the second trench opening 113b. In various embodiments, the trench openings 113a, 113b may have non-uniform shapes and/or sizes. As shown in FIG. 6, the first trench opening 113a may have a width dimension along the first horizontal direction hd1 that is greater than the width dimension of the second trench opening 113b along the first horizontal direction hd1. In some embodiments, the trench openings 113a, 113b may have non-vertical (e.g., angled or curved) sidewalls such that the width dimensions of the trench openings 113a, 113b at the top of the respective trench openings 113a, 113b may be larger than the width dimensions of the trench openings 113a, 113b at the bottom of the trench openings 113a, 113b. Following the etching process, the patterned mask 112 may be removed via a suitable process, such as by ashing or by dissolution using a solvent.

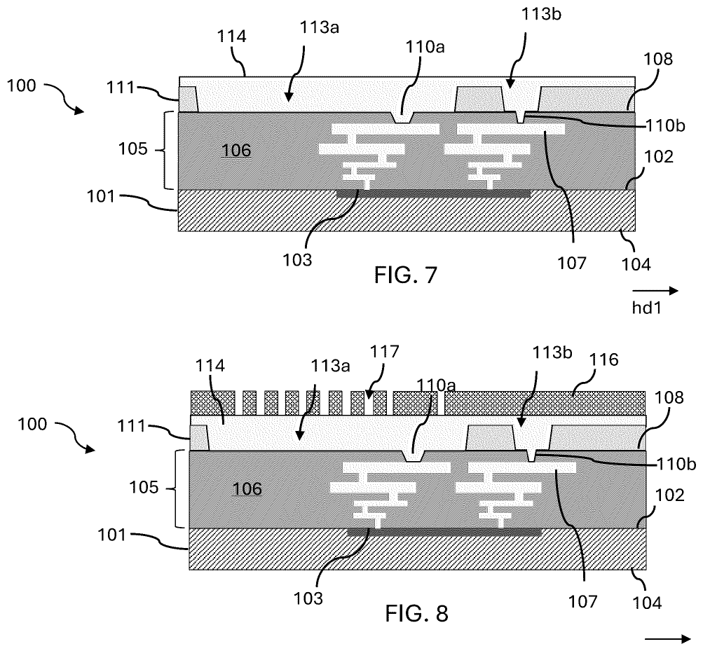

FIG. 7 a vertical cross-sectional view illustrating the first device structure 100 including a metal material 114 within the first and second via openings 110a, 110b and the first and second trench openings 113a, 113b, and over the upper surface of the first dielectric layer 111 according to various embodiments of the present disclosure. Referring to FIG. 7, a metal material 114 may be formed within the via openings 110a, 110b and the trench openings 113a, 113b. In some embodiments, the metal material 114 may fill the entire volume of each of the via openings 110a, 110b and the entire volume of each of the trench openings 113a, 113b, and may optionally be located over the upper surface of the first dielectric layer 111. In other embodiments, the metal material 114 may fill the entire volume of each of the via openings 110a, 110b, and may at least partially fill each of the trench openings 113a, 113b, but may not be present over the upper surface of the first dielectric layer 111.

The metal material 114 may include a suitable metal material, such as copper (Cu), tungsten (W), aluminum (Al), etc., including combinations and alloys thereof. Other suitable metal materials may be within the contemplated scope of disclosure. The metal material 114 may be formed using a suitable deposition process, such as, for example, electrochemical deposition (e.g., electroplating), physical vapor deposition (PVD), sputtering, chemical vapor deposition (CVD), atomic layer deposition (ALD), plasma-enhanced chemical vapor deposition (PECVD), or combinations thereof. In some embodiments, the metal material 114 may include copper that is formed using an electroplating (ECP) technique. In some embodiments, an optional seed layer including copper may be formed over the via openings 110a, 110b, the trench openings 113a, 113b, and optionally over the first dielectric layer 111, using a suitable deposition method, such as sputtering. An electroplating process may be used to form bulk copper material over the seed layer to fill the remaining volume the via openings 110a, 110b, and at least a portion of the volume trench openings 113a, 113b, and optionally over the upper surface of the first dielectric layer 111.

FIG. 8 a vertical cross-sectional view illustrating the first device structure 100 including a patterned mask 116 over the metal material 114 according to various embodiments of the present disclosure. Referring to FIG. 8, a patterned mask 116 may be formed over the upper surface of the metal material 114. The patterned mask 116 may be formed by depositing continuous layer of photosensitive material (e.g., photoresist) over the upper surface of the metal material 114 and patterning the continuous layer of photosensitive material using photolithographic techniques to form a plurality of openings through the mask 116, as described above with reference to FIG. 2. In some embodiments, the openings through the mask 116 may be located over the portion of the metal material 114 that fills the first trench opening 113a, and the mask 116 may not include any openings over the portion of the metal material 114 that fills the second trench opening 113b. In the embodiment shown in FIG. 8, the openings through the patterned mask 116 have substantially identical sizes and shapes, although it will be understood that the openings through the patterned mask 116 may have non-uniform sizes and/or shapes.

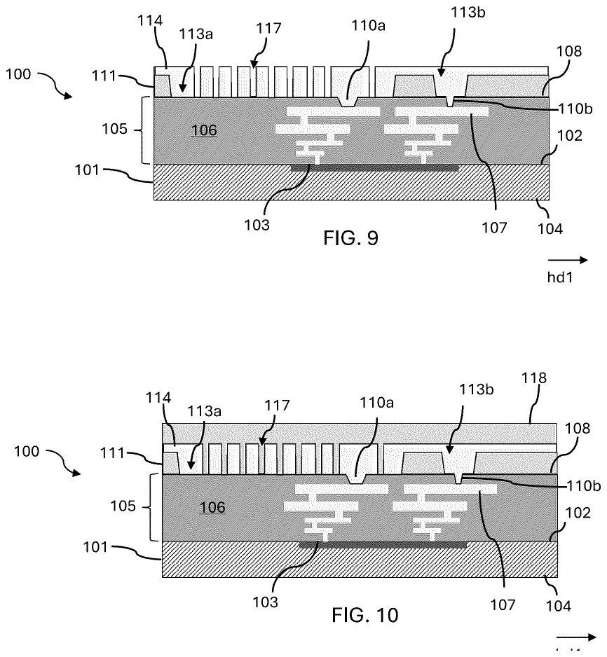

FIG. 9 is a vertical cross-section view of the first device structure 100 following an etching process that forms openings 117 in the metal material 114 according to various embodiments of the present disclosure. Referring to FIG. 9, an etching process may be performed through the patterned mask 116 to remove portions of the metal material 114 that are exposed through the openings in the patterned mask 116 and provide a plurality of openings 117 in the metal material 114. In the embodiment of FIG. 9, the etching process may continue through the entire thickness of the metal material 114 and may stop at the dielectric material 106 of the first interconnect structure 105 such that the dielectric material 106 may be exposed at the bottom of the openings 117. In other embodiments, the etching process may stop within the metal material 114 such that the openings 117 do not extend through the entire thickness of the metal material 114. The openings 117 may be located within the first trench opening 113a in the first dielectric layer 111. Following the etching process, the patterned mask 116 may be removed via a suitable process, such as by ashing or by dissolution using a solvent

The openings 117 in the metal layer 114 may have substantially identical sizes and shapes or may have non-uniform sizes and/or shapes. The openings 117 may have any suitable shape in horizontal cross-section, such as a rectangular shape, a circular shape, an elliptical shape, an irregular shape, etc. In some embodiments, each of the openings 117 may be laterally surrounded by the metal material 114 on all sides of the openings 117.

FIG. 10 a vertical cross-sectional view illustrating the first device structure 100 including a dielectric fill material 118 over the metal material 114 and within the openings 117 in the metal material 114 according to various embodiments of the present disclosure. Referring to FIG. 10, a dielectric fill material 118 may be formed over the upper surface of the metal material 114 and within the openings 117 in the metal material 114. The dielectric fill material 118 may fill the entire volume of each of the openings 117 in the metal material 114. In embodiments in which the openings 117 extend through the entire thickness of the metal material 114, the dielectric fill material 118 may contact the upper surface of the dielectric material 106 of the first interconnect structure 105 at the bottom of each of the openings 117.

The dielectric fill material 118 may include a suitable dielectric material and may be deposited using a suitable deposition process as described above. In some embodiments, the dielectric fill material 118 may include an oxide material, such as silicon oxide, although it will be understood that other dielectric materials may also be utilized.

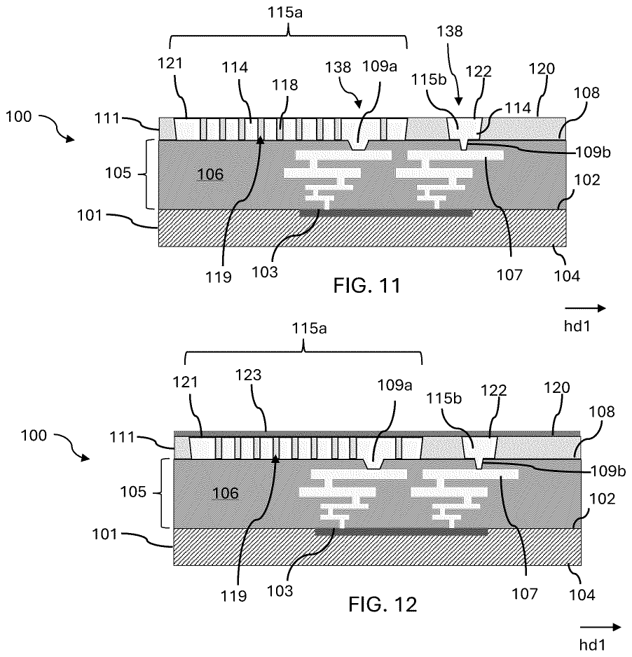

FIG. 11 is a vertical cross-section view of the first device structure 100 following a planarization process that removes the metal material 114 and the dielectric fill material 118 from over the upper surface 120 of the first dielectric layer 111 according to various embodiments of the present disclosure. Referring to FIG. 11, a planarization process, such as a chemical mechanical planarization (CMP) process may be performed to remove portions of the metal material 114 and the dielectric fill material 118 from over the first dielectric layer 111. In some embodiments, the planarization process may also remove a portion of the first dielectric layer 111. Following the planarization process, a discrete first redistribution layer (RDL) pad 115a comprising the metal material 114 and slots 119 including the dielectric fill material 118 may be located within the first trench opening 113a and a discrete second RDL pad 115b comprising the metal material 114 may be located within the second trench opening 113b. A first redistribution layer via (RV) 109a may extend between the lower surface of the first RDL pad 115a and a metal feature 107 of the first interconnect structure 105, and a second RV 109b may extend between the lower surface of the second RDL pad 115b and a metal feature 107 of the first interconnect structure 105. In various embodiments, the first RV 109a may have a larger horizontal width dimension (e.g., diameter) than the second RV 109b. In various embodiments, the first RDL pad 115a may have a width dimension along at least one horizontal direction (e.g., hd1 in FIG. 11) that is greater than the corresponding width dimension of the second RDL pad 115b. The first RDL pad 115a and the second RDL pad 115b may each be laterally surrounded by the first dielectric layer 111. In some embodiments, the first RDL pad 115a and the second RDL pad 115b may have non-vertical (e.g., angled or curved) sidewalls such that the width dimensions of the RDL pads 115a, 115b at the top of the respective RDL pads 115a, 115b may be larger than the width dimensions of the RDL pads 115a, 115b at the bottom of the RDL pads 115a, 115b.

Referring again to FIG. 11, the first RDL pad 115a includes a plurality of discrete slots 119 filled with a dielectric material (e.g., silicon oxide). Each slot 119 may be laterally surrounded by the metal material of the first RDL pad 115a. In the embodiment of FIG. 11, the slots 119 extend through the entire thickness of the first RDL pad 115a and contact the upper surface 108 of the dielectric material 106 of the first interconnect structure 105. In other embodiments, the slots 119 may not extend through the entire thickness of the first RDL pad 115a and may be surrounded by the metal material of the first RDL pad 115a on the side surfaces and bottom surfaces of the slots 119. The upper surface 121 of the first RDL pad 115a may include at least one landing region 138 that does not include any slots 119. The landing region 138 may have a sufficiently large area to enable a subsequently-formed bonding pad via (BPV) to contact the first RDL pad 115a in the landing region 138. Although the first RDL pad 115a shown in FIG. 11 includes a single landing region 138, it will be understood that the first RDL pad 115a may include multiple landing regions 138 such that the RDL pad 115a may be electrically connected to multiple bonding pads via a plurality of BPVs.

The upper surface 122 of the second RDL pad 115b may have a comparatively smaller area than the upper surface 121 of the first RDL pad 115a. The landing region 138 of the second RDL pad 115b may therefore take up a much larger percentage of the overall surface area of the second RDL pad 115b. Thus, relatively smaller RDL pads of the first device structure 100, such as the second RDL pad 115b shown in FIG. 11, may not include slots 119 in various embodiments. Although FIG. 11 illustrates a first device structure 100 including two RDL pads 115a and 115b, it will be understood that a first device structure 100 according to various embodiments may include more than two RDL pads. In some embodiments, the RDL pads may have variable shapes and/or sizes, where the relatively larger RDL pads may include at least one slot 119 as shown in FIG. 11, and relatively smaller RDL pads may optionally lack slots 119.

In related bonded device structures, after the RDL pads have been formed by an ECP process, they are typically subjected to a passivation process that includes forming one or more passivation layers over the as-deposited RDL pads. The passivation layer(s) may optionally be planarized, bonding layer(s) may be formed over the passivation layers, and the bonding pad vias (BPVs) may be formed through the passivation layer(s) to contact the upper surfaces of the RDL pads. Thus, in these related structures, the RDL pads are not subjected to a planarization process as described above with reference to FIG. 11. However, variations in the surface morphology of RDL pads formed by ECP can have a significant effect on the reliability and performance of the bonded device structures. In some cases, for example, there may be significant differences in elevation in the upper surfaces of the RDL pads that provide the landing regions for the BPVs. In addition, differences in the dimensions of the redistribution layer vias (RVs) 109a, 109b such as shown in FIG. 11 may cause differences in the loading effect on the surfaces of the RDL pads. These differences in surface morphology of the RDL pads may produce reliability issues, including increases in surface resistance, skin effect and/or EM effect. In addition, forming the passivation layer(s) and BPVs on non-uniform RDL pad surfaces may also lead to reliability issues, such as over-etching, metal (e.g., Cu) loss, delamination at the RDL pad/passivation material interface, and other defects after subsequent thermal processing.

In various embodiments, performing a planarization process, such as a CMP process, on the metal material of the RDL pads after ECP deposition, may provide RDL pads having consistent, substantially flat upper surfaces with minimal differences in surface elevation. This is illustrated in FIG. 11, which shows the first device structure 100 with a substantially planar upper surface formed by the upper surface 120 of the first dielectric layer 111, the upper surface 121 of the first RDL pad 115a, and the upper surface 123 of the second RDL pad 115b. In various embodiments, following the planarization process, the thickness of the first dielectric layer 111, the first RDL pad 115a, and second RDL pad 115b may be less than 10 μm, such as between about 0.1 μm and about 5 μm.

In addition, providing slots 119 in at least some of the RDL pads 115a such as shown in FIG. 11 may help to provide a flatter upper surface 121 for the RDL pads 115a by reducing erosion and dishing effects on the upper surfaces 121 of the RDL pads 115a. The metal material (e.g., Cu) of the RDL pads may be softer than the surrounding dielectric material (e.g., silicon oxide) making the metal material more susceptible to the chemical slurry used during the planarization (e.g., CMP) process and resulting in a faster polishing rate of the RDL pads compared to the surrounding dielectric material. This may result in a lower metal thickness than anticipated (i.e., “erosion”) and produce a concave shape to the upper surfaces of the metal RDL pads where the central regions of the RDL pads may be recessed relative to the edges of the RDL pads (i.e., “dishing”). These effects may be more pronounced when the metal area to the polishing pad area ratio is high, such as for relatively larger-sized RDL pads. Providing slots 119 filled with dielectric material within at least some of the RDL pads may mitigate the effects of erosion and dishing effects by decreasing the metal area to polishing pad ratio, thereby providing a flatter upper surface 121 of the RLD pad 115a.

Accordingly, by performing a planarization (e.g., CMP) process on the metal material of the RDL pads after ECP deposition, and by forming dielectric-filled slots 119 in the metal material of larger-sized RDL pads prior to planarization, the overall uniformity and flatness of the upper surfaces of the RDL pads may be increased. Accordingly, device reliability and performance may be improved by mitigating elevation differences, conduction effects, and other defects, and ensuring consistent and precise landing regions for the BPVs.

FIG. 12 is a vertical cross-section view of the first device structure 100 illustrating a second dielectric layer 123 over the upper surface 120 of the first dielectric layer 111, the upper surface 121 of the first RDL pad 115a, and the upper surface 122 of the second RDL pad 115b according to various embodiments of the present disclosure. Referring to FIG. 12, a second dielectric layer 123 may be deposited over the upper surface 120 of the first dielectric layer 111, the upper surface 121 of the first RDL pad 115a, and the upper surface 122 of the second RDL pad 115b. The second dielectric layer 123 may include a suitable dielectric material. In some embodiments, the second dielectric layer 123 may include an inorganic dielectric material with low dielectric constant, such as undoped silicon glass, silicon nitride, silicon oxide, carbon-doped silicon dioxide, etc. Other suitable materials for the second dielectric layer 123 are within the contemplated scope of disclosure. The second dielectric layer 123 may be deposited using a suitable deposition process as described above. The second dielectric layer 123 may have the same or a different composition as the first dielectric layer 111. In various embodiments, the thickness of the second dielectric layer 123 may be less than the thickness of the first dielectric layer 111. In various embodiments, the second dielectric layer 123 may function as a passivation layer for the underlying RDL pads 115a, 115b.

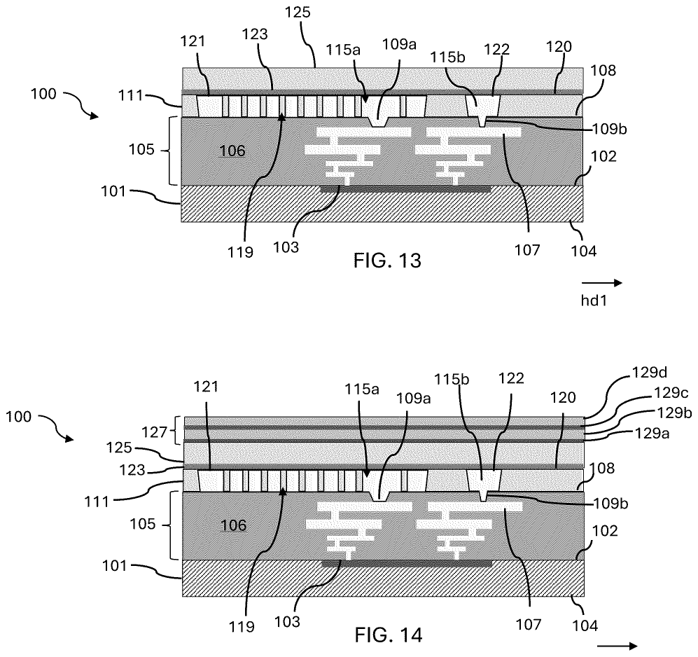

FIG. 13 is a vertical cross-section view of the first device structure 100 illustrating a third dielectric layer 125 over the second dielectric layer 123 according to various embodiments of the present disclosure. Referring to FIG. 13, a third dielectric layer 125 may be deposited over the upper surface of the second dielectric layer 123. The third dielectric layer 125 may include a suitable dielectric material. In some embodiments, the third dielectric layer 125 may include an inorganic dielectric material with low dielectric constant, such as undoped silicon glass, silicon nitride, silicon oxide, carbon-doped silicon dioxide, etc. Other suitable materials for the third dielectric layer 125 are within the contemplated scope of disclosure. The third dielectric layer 125 may function as an additional passivation layer for the underlying RDL pads 115a, 115b. The third dielectric layer 125 may be deposited using a suitable deposition process as described above.

In various embodiments, the thickness of the third dielectric layer 125 may be greater than the thickness of the second dielectric layer 123. In some embodiments, the thickness of the third dielectric layer 125 may be less than 10 μm, such as between about 0.1 μm and about 5 μm. In various embodiments, the second dielectric layer 123 and the third dielectric layer 125 may have different compositions. The second dielectric layer 123 may have a higher etch resistivity than the etch resistivity of the third dielectric layer 125 to an etch chemistry used during a subsequent etching step described in further detail below. Thus, the second dielectric layer 123 may also be referred to as an etch stop layer. In one non-limiting embodiment, the second dielectric layer 123 may include a nitride material (e.g., SiN), and the third dielectric layer 125 may include an oxide material (e.g., SiO).

FIG. 14 is a vertical cross-section view of the first device structure 100 illustrating a first bonding layer 127 over the third dielectric layer 125 according to various embodiments of the present disclosure. Referring to FIG. 14, a first bonding layer 127 may be deposited over the upper surface of the third dielectric layer 125. The first bonding layer 127 may include at least one layer of dielectric material. In the embodiment of FIG. 14, the first bonding layer 127 includes four layers of dielectric material 129a, 129b, 129c and 129d, although it will be understood that the first bonding layer 127 may include more or less layers of dielectric material. The layers of dielectric material 129a-129d may each be composed of a suitable dielectric material, such as silicon oxide, silicon nitride, silicon carbide, silicon carbon nitride, silicon oxynitride, a dielectric polymer material, or the like. Other suitable dielectric materials are within the contemplated scope of disclosure. The layers of dielectric material 129a-129d may be deposited by a suitable deposition process as described above. In the embodiment of FIG. 14, layers 129b and 129d may be thicker than layers 129a and 129c. In some embodiments, adjacent layers of dielectric material 129a-129d may have different compositions. In various embodiments, layers 129a and 129c may function as etch stop layers as described above. The uppermost layer of dielectric material of the first bonding layer 127 (i.e., layer 129d in FIG. 14) may have a planar upper surface.

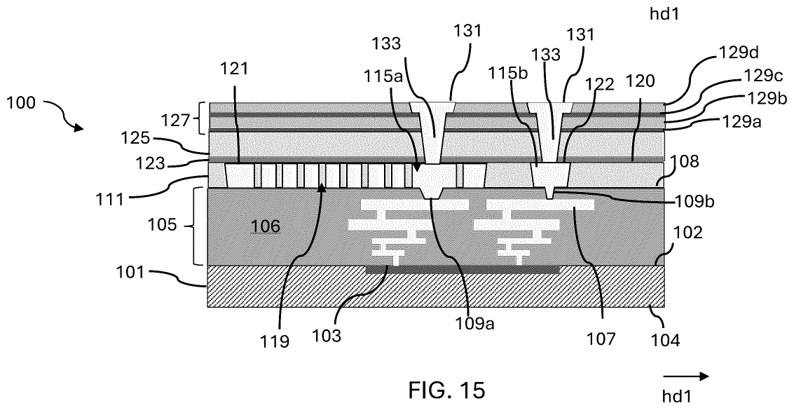

FIG. 15 is a vertical cross-section view of the first device structure 100 illustrating bonding pads 131 formed within the first bonding layer 127 and bonding pad vias (BPVs) 133 extending between the bonding pads 131 and the RDL pads 115a, 115b according to various embodiments of the present disclosure. Referring to FIG. 15, an etching process may be performed through a photolithographically-patterned mask to form via openings through the dielectric material layers 129a-129d of the first bonding layer 127, the third dielectric layer 125, and the second dielectric layer 123. The landing regions 138 (see FIG. 11) on the upper surfaces 121, 122 of the first and second RDL pads 115a and 115b may be exposed at the bottom of the via openings. The mask may be removed, and an additional photolithographically-patterned mask may be formed over the first bonding layer 127. Another etching process may be performed through the additional mask to form trench openings in at least the uppermost dielectric material layer 129d of the first bonding layer 127, and the additional mask may be removed. A metal material (e.g., Cu, W, Al, etc., including combinations and alloys thereof) may be deposited within the trench openings and the via openings using a suitable deposition process to form the bonding pads 131 and the BPVs 133 extending between the bonding pads 131 and the landing regions 138 on the upper surfaces 121, 122 of the first and second RDL pads 115a and 115b. A planarization process, such as a CMP process, may optionally be performed to remove any excess metal material from over the upper surface of the uppermost dielectric material layer 129d of the first bonding layer 127 such that the upper surface of each of the bonding pads 131 may be substantially coplanar with the upper surface of dielectric material layer 129d of the first bonding layer 127.

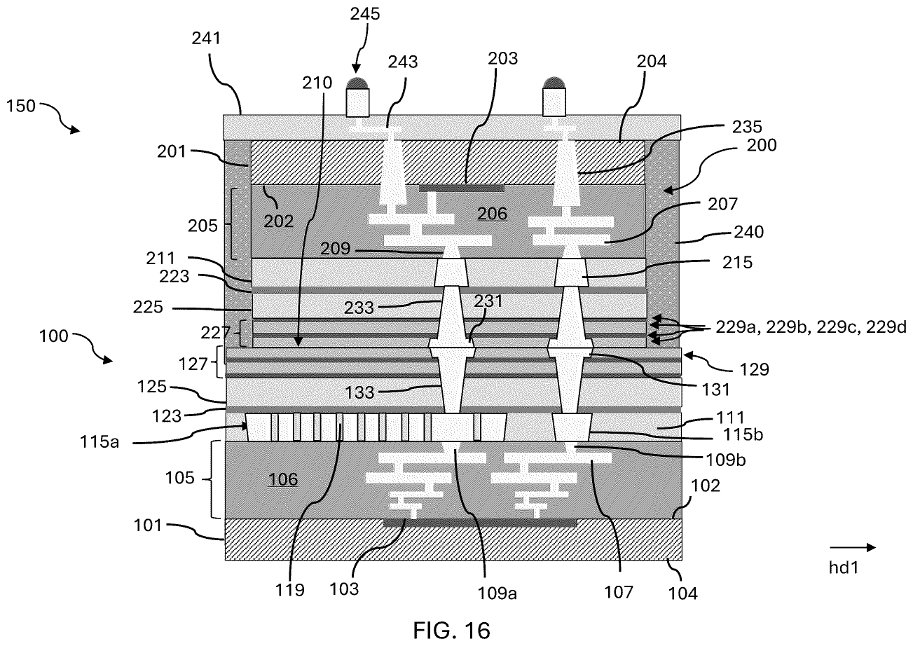

FIG. 16 is a vertical cross-section view illustrating the first device structure 100 bonded to a second device structure 200 to form a bonded device structure 150 according to various embodiments of the present disclosure. Referring to FIG. 16, the second device structure 200 may include a second semiconductor substrate 201 having a first major surface (i.e., a front side surface 202) and a second major surface (i.e., a backside surface 204). A plurality of devices 203 may be disposed on, over and/or in the front side surface 202 of the second semiconductor substrate 201. The second device structure 200 may also include a second interconnect structure 205 over the front side surface 202 of the second semiconductor substrate 201. The second interconnect structure 205 may include metal features 207 (e.g., metal lines, vias, bonding pads, etc.) formed within a dielectric material 206. In some embodiments, the second device structure 200 may also include one or more through-substrate vias (TSVs) 235 extending through the second semiconductor substrate 201.

The second semiconductor structure 200 may also include RDL pads 215 over the second interconnect structure 205 and laterally surrounded by a first dielectric layer 211, where each RDL pad 215 may be electrically coupled to an underlying metal feature 207 of the second interconnect structure 200 by a redistribution layer via (RV) 209. The RDL pads 215, first dielectric layer 211 and RVs 209 of the second device structure 200 may be similar or identical to the RDL pads 115a, 115b, first dielectric layer 111 and RVs 109a, 109 of the first semiconductor structure 100 described above. Thus, repeated discussion of like elements is omitted for brevity. Although not shown in FIG. 16, it will be understood that at least some of the RDL pads 215 of the second device structure 200 may include slots 119 filled with dielectric material as described above.

In various embodiments, the second device structure 200 may additionally include one or more passivation layers, such as a second dielectric layer 223 (i.e., an etch-stop layer) and a third dielectric layer 225 formed over the RDL pads 215 and the first dielectric layer 211. A second bonding layer 227 may be formed over the passivation layer(s) 223, 225. The second bonding layer 227 may be similar or identical to the first bonding layer 127, and may include may include at least one layer of dielectric material 229a, 229b, 229c and 229d, a plurality of bonding pads 231 embedded in the layer(s) of dielectric material 229a, 229b, 229c and 229d, and bonding pad vias (BPVs) 233 extending from the bonding pads 231 through the layer(s) of dielectric material 229a, 229b, 229c and 229d and the passivation layers 223, 225 and contacting the RDL pads 215. In various embodiments, the layout of the bonding pads 231 of the second bonding layer 227 of the second device structure 200 may correspond to the layout of the bonding pads 131 of the first bonding layer 131 of the first device structure 100.

Referring again to FIG. 16, a bonding process may be performed to bond the second device structure 200 to the first device structure 100 and form the bonded device structure 150. In various embodiments, the second device structure 200 may be aligned over the first device structure 100 such that the second bonding layer 227 on the second device structure 200 faces the first bonding layer 127 on the first device structure 100. Bonding pads of the second bonding layer 227 may be aligned with corresponding bonding pads 131 of the first bonding layer 127. In various embodiments, the second bonding layer 227 may be bonded to the first bonding layer 127 via a metal-to-metal (M-M) and dielectric-to-dielectric (D-D) direct bonding technique to couple the second device structure 200 mechanically and electrically to the first device structure 100. In some embodiments, prior to bonding the second device structure 200 to the first device structure 100, the surfaces of the first bonding layer 127 on the first device structure 100 and/or the second bonding layer 227 on the second device structure 200 may optionally be subjected to a pre-treatment process (e.g., a plasma treatment process) to promote surface activation of the first bonding layer 127 and/or the second bonding layer 227 prior to bonding the second device structure 200 to the first device structure 100.

To perform the bonding process, the second device structure 200 and the first device structure 100 may be brought together such that the second bonding layer 227 of the second device structure 200 contacts the first bonding layer 127 of the first device structure 100. The second device structure 200 and the first device structure 100 may be aligned such that bonding pads 231 of the second bonding layer 227 contact corresponding bonding pads 131 of the first bonding layer 127 and the dielectric material layer 229d of the second bonding layer 227 contacts the dielectric material layer 129d of the first bonding layer 127. In a direct bonding process, such as a metal-to-metal (M-M) and dielectric-to-dielectric (D-D) bonding process, bringing the first bonding layer 127 and the second bonding layer 227 into contact with one another may result in a pre-bonding process in which chemical bonds (e.g., hydrogen bridge bonds) may form at the planar interface between the dielectric material of the first bonding layer 127 and the dielectric material of the second bonding layer 227. In some embodiments, the pre-bonding process may be performed at ambient temperature (e.g., ˜20° C.). In other embodiments, the pre-bonding process may be performed at an elevated temperature. In some embodiments, a compressive force may be applied to the second device structure 200 and the first device structure 100 during the pre-bonding process. In other embodiments, no compressive force may be applied during the pre-bonding process.

Referring again to FIG. 16, in some embodiments, an annealing process may be performed to complete the bonding of the bonding pads 131 of the first bonding layer 127 to the bonding pads 131 of the second bonding layer 227 according to various embodiments of the present disclosure. The annealing process may be performed at an elevated temperature, such as 100° C. or more, such as between about 150° C. and about 350° C., although lower and higher temperatures may also be utilized. In some embodiments, a compressive force may be applied to the second device structure 200 and the first device structure 100 during the annealing process. In other embodiments, no compressive force may be applied during the annealing process.

Following the bonding process, the bonded device structure 150 may include a second device structure 200 that is mechanically and electronically coupled to a first device structure 100 at a bonding interface 210. In the embodiment of FIG. 16, bonded device structure 150 includes a configuration in which the front sides of the first device structure 100 and the second device structure 200 (i.e., the sides opposite the first semiconductor substrate 101 and the second semiconductor substrate 101) are bonded to one another in a “front-to-front” configuration. However, it will be understood that other embodiments of the bonded device structure 150 may have a different configuration, such as a front-to-back configuration or a back-to-back configuration.

In the embodiment of FIG. 16, the second device structure 200 may include a semiconductor die. A gap fill dielectric material 240 composed of a suitable dielectric material may optionally laterally surround the second device structure 200 and may contact the first device structure 100. In some embodiments, one or more dielectric material layers 241 composed of a suitable dielectric material may be formed over the back side 204 of the second semiconductor substrate 201. Metal interconnect features 243 may be formed within the dielectric material layer(s) 241 and may electrically contact TSVs 235 of the second device structure 200. Bonding structures 245, such as metal pillars capped by a solder material, may be formed over the dielectric material layer(s) 241 and in electrical contact with the metal interconnect features 243. Other suitable bonding structures 245 are within the contemplated scope of disclosure. The bonding structures 245 may be used to mount the bonded device structure 150 to a support structure, such as a substrate, an interposer, a printed circuit board (PCB), or the like.

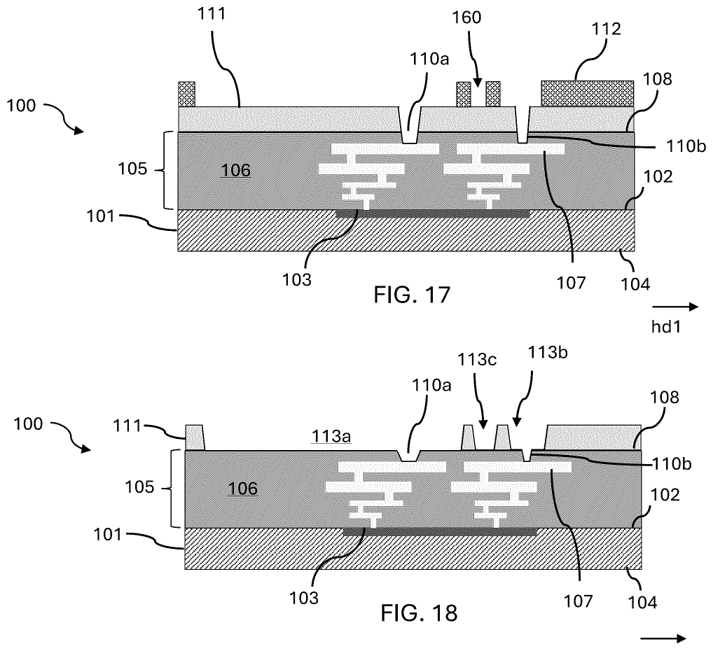

FIGS. 17-22 are sequential vertical cross-sectional views illustrating intermediate structures during a process of fabricating a bonded device structure including at least one dummy RDL pad according to another embodiment of the present disclosure. FIG. 17 a vertical cross-sectional view illustrating a first device structure 100 including a patterned mask 112 over the first dielectric layer 111 according to various embodiments of the present disclosure. The first device structure 100 shown in FIG. 17 may be derived from the first device structure 100 described above with reference to FIG. 5. Thus, repeated discussion of like elements is omitted for brevity. The first device structure 100 in the embodiment of FIG. 17 differs from the first device structure 100 of FIG. 5 in that the patterned mask 112 includes openings corresponding to the locations of RDL pads 115a, 115b to be subsequently formed as described above in addition to an opening 160 corresponding to the location of a dummy RDL pad to be subsequently formed. Each of the openings corresponding to the location of an RDL pad 115a, 115b may expose at least one via openings 110a, 110b through the first dielectric layer 111 and the dielectric material 106 of the first interconnect structure 105. In various embodiments, the opening 160 corresponding to the location of the dummy RDL pad may not expose a via opening.

FIG. 18 is a vertical cross-section view of the first device structure 100 following an etching process that forms trench portions 113a, 113b and 113c the first dielectric layer 111 according to various embodiments of the present disclosure. Referring to FIG. 18, an etching process may be performed through the patterned mask 112 as described above with reference to FIG. 6. The etching process may form a plurality of trench openings 113a, 113b, 113c extending through the first dielectric layer 111. The embodiment of FIG. 18 illustrates three trench openings, including a first trench opening 113a, a second trench opening 113b, and a third trench opening 113c. The first and second trench openings 113a and 113b expose and are continuous with the first via opening 110a and the second via opening 110b, respectively. The third trench opening 113c may not expose any via openings. That is, the upper surface 118 of the dielectric material 106 of the first interconnect structure 105 may extend continuously over the bottom surface of the third trench opening 113c. In the embodiment shown in FIG. 18, the third trench opening 113c is located between the first trench opening 113a and the second trench opening 113b. Although FIG. 18 illustrates a single third trench opening 113c, it will be understood that the first device structure 100 may include a plurality of third trench openings 113c. The size and/or shape of the third trench opening 113c may be the same as or different than the first trench opening 113a and/or the second trench opening 113b. In some embodiments, the width dimension of the third trench opening 113c along at least one horizontal direction (i.e., hd1 in FIG. 18) may be less than the width dimension of the first trench opening 113a and optionally less than the width dimension of the second trench opening 113b along the same horizontal direction hd1. In some embodiments, the third trench opening 113c may have non-vertical (e.g., angled or curved) sidewalls such that the width dimensions of the third trench opening 113c are larger at the top of the third trench opening 113c than at the bottom of the third trench opening 113c. Following the etching process, the patterned mask 112 may be removed via a suitable process, such as by ashing or by dissolution using a solvent.

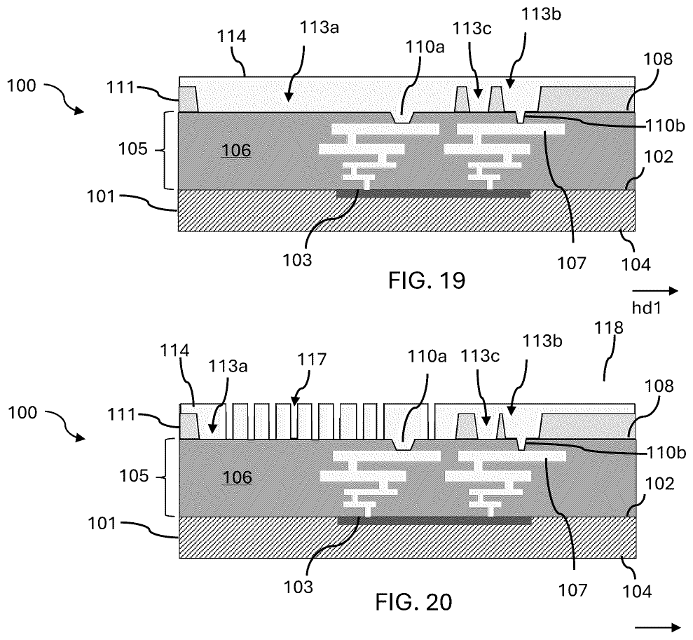

FIG. 19 a vertical cross-sectional view illustrating the first device structure 100 including a metal material 114 within the first and second via openings 110a, 110b and the first, second and third trench openings 113a, 113b, 113c, and over the upper surface of the first dielectric layer 111 according to various embodiments of the present disclosure. Referring to FIG. 19, a metal material 114 may be deposited within the via openings 110a, 110b and the trench openings 113a, 113b, 113c and optionally over the upper surface of the first dielectric layer 111 as described above with reference to FIG. 7. In some embodiments, the metal material 114 may include copper that is formed using an electroplating (ECP) technique.

FIG. 20 is a vertical cross-section view of the first device structure 100 including openings 117 in the metal material 114 according to various embodiments of the present disclosure. Referring to FIG. 20, a patterned mask including openings through the mask located over the portion of the metal material 114 that fills the first trench opening 113a may be formed over the metal material 114 as described above with reference to FIG. 8. An etching process may then be performed through the patterned mask to remove portions of the metal material 114 that are exposed through the openings in the patterned mask 116 and provide a plurality of openings 117 in the metal material 114 as described above with reference to FIG. 9. The openings 117 may be located within the first trench opening 113a in the first dielectric layer 111. In various embodiments, no openings 117 may be formed in the metal material within the second trench opening 113b or the third trench opening 113c. Following the etching process, the patterned mask may be removed via a suitable process, such as by ashing or by dissolution using a solvent.

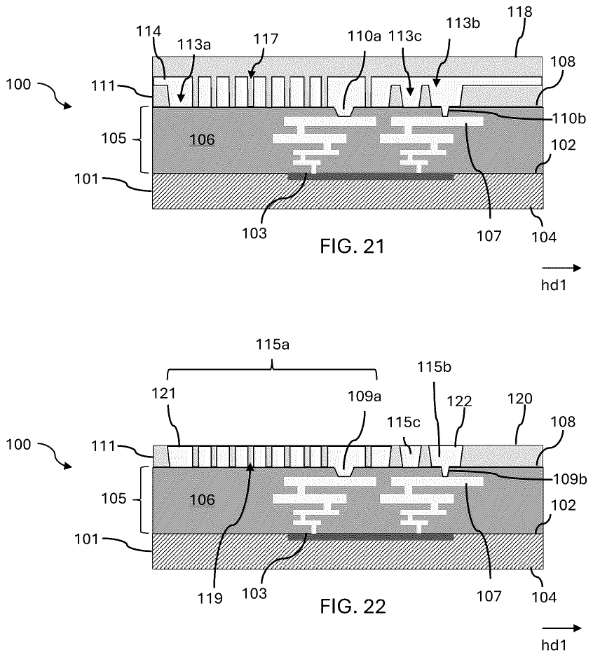

FIG. 21 a vertical cross-sectional view illustrating the first device structure 100 including a dielectric fill material 118 over the metal material 114 and within the openings 117 in the metal material 114 according to various embodiments of the present disclosure. Referring to FIG. 21, a dielectric fill material 118 may be formed over the upper surface of the metal material 114 and within the openings 117 in the metal material 114 as described above with reference to FIG. 10.

FIG. 22 is a vertical cross-section view of the first device structure 100 following a planarization process that removes the metal material 114 and the dielectric fill material 118 from over the upper surface 120 of the first dielectric layer 111 according to various embodiments of the present disclosure. Referring to FIG. 22, a planarization process, such as a chemical mechanical planarization (CMP) process may be performed to remove portions of the metal material 114 and the dielectric fill material 118 from over the first dielectric layer 111 as described above with reference to FIG. 11. Following the planarization process, a discrete first redistribution layer (RDL) pad 115a comprising the metal material 114 and slots 119 including the dielectric fill material 118 may be located within the first trench opening 113a, discrete second RDL pad 115b comprising the metal material 114 may be located within the second trench opening 113b, and a discrete third RDL pad 115c may be located within the third trench opening 113c. A first redistribution layer via (RV) 109a may extend between the lower surface of the first RDL pad 115a and a metal feature 107 of the first interconnect structure 105, and a second RV 109b may extend between the lower surface of the second RDL pad 115b and a metal feature 107 of the first interconnect structure 105. In various embodiments, the dielectric material 106 of the first interconnect structure 105 may extend over the entire lower surface of the third RDL pad 115c and no RV may contact the lower surface of the third RDL pad 115c. The first RDL pad 115a, the second RDL pad 115b, and the third RDL pad 115c may each be laterally surrounded by the first dielectric layer 111. In some embodiments, the first RDL pad 115a, the second RDL pad 115b, and the third RDL pad 115c may have non-vertical (e.g., angled or curved) sidewalls such that the width dimensions of the RDL pads 115a, 115b, 115c at the top of the respective RDL pads 115a, 115b, 115c may be larger than the width dimensions of the RDL pads 115a, 115b, 115c at the bottom of the RDL pads 115a, 115b, 115c.

In various embodiments, the third RDL pad 115c may also be referred to as a “dummy” RDL pad 115c because it may not be a functional RDL pad 115c in the first device structure 105 or in the bonded device structure 150. That is, while the first RDL pad 115a and the second RDL pad 115b may each function to electrically connect subsequently-formed BPVs 133 to underlying RVs 109a, 109b and metal features 107 of the first interconnect structure 105, the “dummy” third RDL pad 115c may not provide an electrical pathway between a BPV 133 and an underlying RV 109 or metal feature 107 of the first device structure 100. In some embodiments, the “dummy” RDL pad 115c may not contact either a BPV 133 or an RV 109 in the finished first device structure 105.

In various embodiments, providing at least one “dummy” RDL pad 115c may help to improve the uniformity of the planarization (e.g., CMP) process which may help to improve the flatness of the upper surface of the first device structure 100. In various embodiments, the at least one dummy RDL pad 115c may be located between or adjacent to functional RDL pads 115a, 115b. The presence of the dummy RDL pad(s) 115c may help to provide a more uniform ratio of metal to dielectric material that contacts the polishing pad during the planarization process. This may help to minimize uneven material removal and mitigate erosion and dishing effects as described above. Accordingly, the planarity of the upper surface of the first device structure 100 formed by the upper surface 120 of the first dielectric layer 111, the upper surface 121 of the first RDL pad 115a, the upper surface 123 of the second RDL pad 115b, and upper surface of the dummy RDL pad 115c may be improved.

The processing operations described above with reference to FIGS. 12-15 may then be performed on the first device structure 100 shown in FIG. 21 to form one or more passivation layers, such as a second dielectric layer 123 (i.e., an etch-stop layer) and a third dielectric layer 125, over the RDL pads 115a, 115b, 115c and the first dielectric layer 111 and to form a first bonding layer 127 including at least one layer of dielectric material 129a, 129b, 129c, 129d over the passivation layer(s), a plurality of bonding pads 131 embedded in the layer(s) of dielectric material 129a, 129b, 129c and 129d, and BPVs 133 extending from the bonding pads 131 through the layer(s) of dielectric material 129a, 129b, 129c and 129d and the passivation layers 123, 125 and contacting the first and second RDL pads 115a and 115b. In various embodiments, the BPVs 133 may not contact the dummy RDL pad 115c. A bonding process as described above with reference to FIG. 16 may then be performed to bond the first device structure 100 to a second device structure 200 to form a bonded device structure 150.

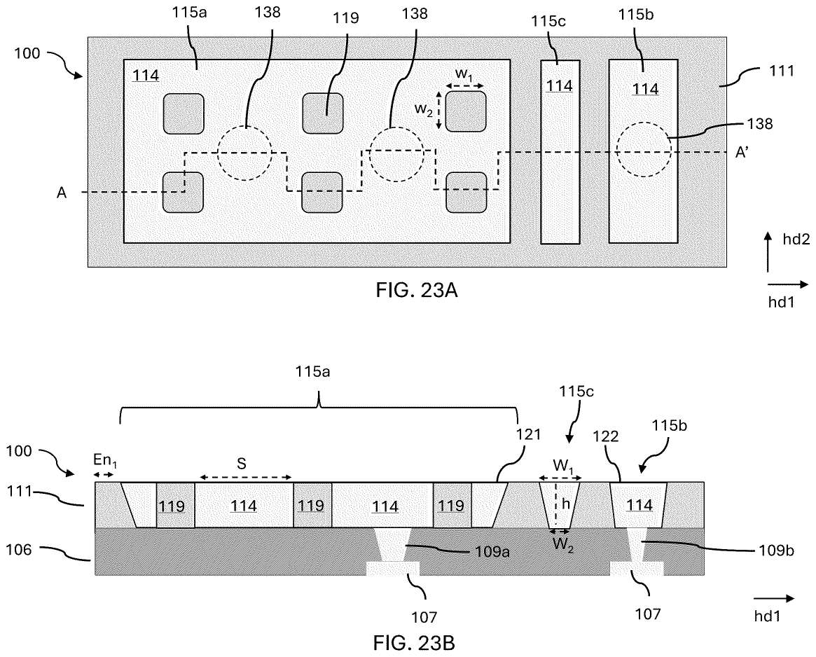

FIG. 23A is a top view of a portion of a first device structure 100 following a planarization process according to an embodiment of the present disclosure. FIG. 23B is a vertical cross-section view of the portion of a first device structure 100 taken along line A-A′ in FIG. 23A. FIGS. 23A and 23B illustrate the layout of the first, second and third RDL pads 115a, 115b and 115c, including the landing regions 138 on the first and second RDL pads 115a and 115b, and the dielectric-filled slots 119 of the first RDL pad 115a according to one non-limiting embodiment. As shown in FIGS. 23A and 23B, the third, or “dummy,” RDL pad 115c is located between the first RDL pad 115a and the second RDL pad 115b. In some embodiments, the dummy RDL pad 115c may have a height dimension, h, that is less than about 10 μm, such as between about 0.1 μm and about 5 μm. The width dimension W₁ of the upper surface of the dummy RDL pad 115 c along the first horizontal dimension hd1 may be greater than the width dimension W₂ of the lower surface of the dummy RDL pad 115c along hd1. In some embodiments, W₁ may be at least about 0.1 μm, such as about 1 μm or more. In some embodiments, the width dimensions of the upper surfaces of the first RDL pad 115a and the second RDL pad 115b along hd1 may be greater than W₁. In some embodiments, the width dimensions of the first RDL pad 115a, the second RDL pad 115b, and the dummy RDL pad 115c may be substantially equal along the second horizontal direction hd2.

Referring to FIG. 23A, each of the slots 119 of the first RDL pad 115a may have a width dimension w₁ along hd1 and a width dimension w₂ along hd2. In some embodiments, w₁ and w₂ may be substantially the same, such as shown in FIG. 23A. Alternatively, w₁ and w₂ may be different. For example, the slots 119 may have an oblong shape, such as a rectangular shape, where w₂>w₁. In various embodiments, w₁ and w₂ may both be greater than about 0.1 μm, such as about 1 μm or more. Other suitable sizes and configurations for the slots 119 are within the contemplated scope of disclosure.

In various embodiments, each of the slots 119 may be laterally surrounded by the metal material 114 of the first RDL pad 115a. Thus, each slot 119 may be spaced from the peripheral edges of the first RDL pad 115a and may also be spaced from other slots 119 of the first RDL pad 115a. Referring to FIG. 23B, in some embodiments, a minimum spacing, or enclosure distance, En₁, between each of the slots 119 and a peripheral edge of the first RDL pad 115a may be at least about 1 μm. In some embodiments, a minimum spacing, S, between each slot 119 and the adjacent slot(s) 119 of the first RDL pad 115a may be at least about 1 μm. In some embodiments, a maximum spacing S between each slot 119 and the adjacent slot(s) 119 of the first RDL pad 115a may be less than about 3 μm. This may help to ensure that the slots 119 occupy a sufficient portion of the first RDL pad 115a to mitigate dishing and erosion effects while providing adequate space for the landing region(s) 138 on the upper surface 121 of the first RDL pad 115a.

In the embodiment of FIGS. 23A-23B, the first RDL pad 115a includes a pair of landing regions 138 with slots 119 distributed evenly around the periphery of each of the landing regions 138. However, it will be understood that other configurations for the first RDL pad 115a are within the contemplated scope of disclosure. In some embodiments, the percentage of the total area of the upper surface 121 of the first RDL pad 115 a that is occupied by the slots 119 may be between about 20% and about 25%, although greater and lesser percentages may also be utilized. In some embodiments, the difference in horizontal elevation of the upper surface 121 of the first RDL pad 115a and the upper surface 122 of the second RDL pad 115b at the adjacent peripheral edges of the first and second RDL pads 115 a, 115 b may be about 0.1 μm or less.

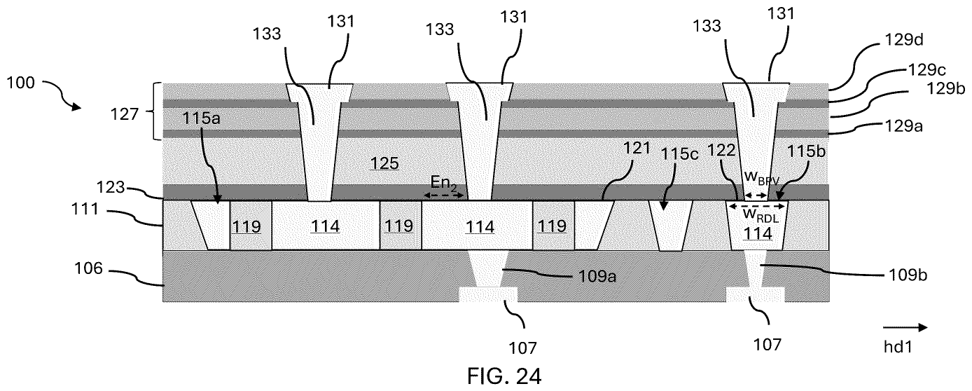

FIG. 24 is a vertical cross-section view of the portion of the first device structure 100 of FIGS. 23A-23B following the formation of passivation layers 123 and 125 over the RDL layers 115a, 115b, 115c, a first bonding layer 127 over the passivation layers 123 and 125, and BPVs 133 extending through the first bonding layer 127 and the passivation layers 123 and 125 and contacting the first RDL pad 115a and the second RDL pad 115b according to various embodiments of the present disclosure. In the embodiment of FIG. 24, two BPVs 133 contact the first RDL pad 115a and one BPV 133 contacts the second RDL pad 115b. No BPVs contact the “dummy” RDL pad 115c. In some embodiments, the BPVs 133 may have a width dimension, W_{BPV}, where the BPVs 133 contact the upper surfaces 121, 122 of the first and second RDL pads 115 a, 115 b. In various embodiments, W_{BPV} may be between about 1.0 μm and about 5 μm, although greater and lesser widths for the BPVs 133 are within the contemplated scope of disclosure. In various embodiments, each of the bonding pads 131 and the BPVs 133 may have substantially uniform sizes and shapes. The first and second RDL pads 115a, 115b that are electrically coupled to the BPVs 133 may have non-uniform sizes and shapes. In some embodiments, the electrical signals transmitted through the first RDL pad(s) 115a may differ from the electrical signals transmitted through the second RDL pad(s) 115b with respect to the voltage, current and/or power characteristics of the respective signals. In some embodiments, multiple BPVs 133 may contact each of the first RDL pads 115a such that electrical signals of a first type may be transmitted in parallel between the first RDL pad 115a and multiple bonding pads 131 of the first bonding layer 127. In contrast, a single PBV 133 may contact each of the second RDL pads 115b and such that electrical signals of a second type may be transmitted between the second RDL pad 115b and a single bonding pad 131 of the bonding layer 127. In some embodiments, the first RV(s) 109a that transmit the electrical signals of the first type between the first RDL pad(s) 115a and the metal features 107 of the first interconnect structure 105 may have a greater width dimension than the second RV(s) 109b that transmit the electrical signals of the second type between the second RDL pad(s) 115b and the metal features 107 of the first interconnect structure.

In some embodiments, the width dimensions of the RDL pads 115a, 115b that are contacted by the BPVs 133, W_{RDL}, may be about 1 μm or more. In some embodiments, a minimum spacing, or enclosure distance, En₂, between each of the BPVs 133 that contact the first RDL pad 115a and the slots 119 of the RDL pad 115a may be at least about 0.5 μm.

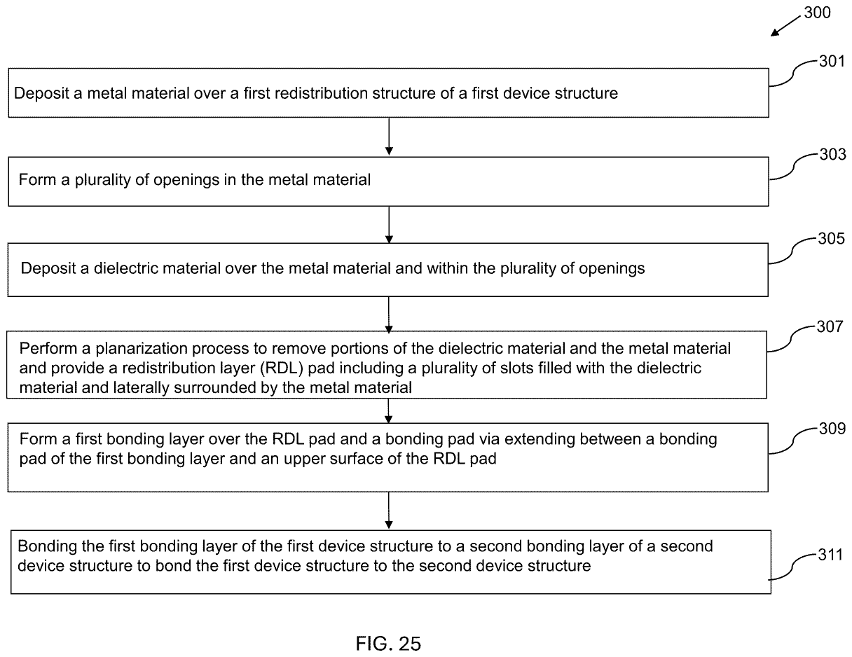

FIG. 25 is a flowchart illustrating a method 300 of fabricating a bonded device structure 150 according to an embodiment of the present disclosure. Referring to FIGS. 7, 19 and 25, in step 301 of method 300, a metal material 114 may be deposited over a first redistribution structure 105 of a first device structure 100. Referring to FIGS. 8, 9, 20 and 25, in step 303 of method 300, a plurality of openings 117 may be formed in the metal material 114. Referring to FIGS. 10, 21 and 25, in step 305 of method 300, a dielectric material 118 may be deposited over the metal material 114 and within the plurality of openings 117. Referring to FIGS. 11, 22-23B and 25, in step 307 of method 300, a planarization process may be performed to remove portions of the dielectric material 118 and the metal material 114 and provide a redistribution layer (RDL) pad 115a including a plurality of slots 119 filled with the dielectric material 118 and laterally surrounded by the metal material 114. Referring to FIGS. 12-15, 24 and 25, in step 309 of method 300, a first bonding layer 127 may be formed over the RDL pad 115a and a bonding pad via 133 may be formed extending between a bonding pad 131 of the first bonding layer 127 and an upper surface 121 of the RDL pad 115a. Referring to FIGS. 16 and 25, in step 311 of method 300, the first bonding layer 127 of the first device structure 100 may be bonded to a second bonding layer 227 of a second device structure 200 to bond the first device structure 100 to the second device structure 200.

Referring to all drawings and according to various embodiments of the present disclosure, a structure 100, 200, 150 includes a first device structure 100 including a first semiconductor substrate 101, first devices disposed 103 on, over and/or in a first side 102 of the first semiconductor substrate 101, a first interconnect structure 105 over the first devices 103 and the first side 102 of the first semiconductor substrate 101, the first interconnect structure 105 including metal features 107 within a dielectric material 106, a first redistribution layer (RDL) pad 115a over the first interconnect structure 105 and electrically coupled to the metal features 107 of the first interconnect structure 105 by a first redistribution layer via 109a, the first RDL pad 115a including a metal material 114 and a plurality of slots 119 filled with dielectric material 118 laterally surrounded by the metal material 114, a first bonding layer 127 over the first RDL pad 115a, the first bonding layer 127 including a bonding pad 131 laterally surrounded by a dielectric material 129, where a bonding pad via 133 is electrically connected to a bonding pad 131 of the first bonding layer 127 and is electrically connected to an upper surface 121 of the first RDL pad 115a.

In one embodiment, the structure 100, 200, 150 includes a second device structure 200 including a second semiconductor substrate 201, second devices 203 disposed on or over a first side 202 of the second semiconductor substrate 201, a second interconnect structure 205 over the second devices 203 and the first side 203 of the second semiconductor substrate 101, the second interconnect structure 105 including metal features 207 within a dielectric material 206, and a second bonding layer 227 over the second interconnect structure 205, the second bonding layer 207 including a bonding pad 231 laterally surrounded by a dielectric material 229 (229a, 229b, 229c, 229d), where the first bonding layer 127 is bonded to the second bonding layer 227 at a bonding interface 210 to bond the first device structure 100 to the second device structure 200.

In another embodiment, the slots 119 extend through an entire thickness of the first RDL pad 115a.

In another embodiment, the slots 119 constitute between 20% and 25% of a total area of the upper surface 121 of the first RDL pad 115a.

In another embodiment, a minimum spacing En₁ between each of the slots 119 and a peripheral edge of the first RDL pad 115 a is at least 1 μm, and a minimum spacing En₂ between each bonding pad via 131 that contacts the upper surface 121 of the first RDL pad 115a and the slots 119 is at least 0.5 μm.

In another embodiment, a minimum spacing S between each slot 119 and the adjacent slot(s) 119 of the first RDL pad 115a is at least 1 μm, and a maximum spacing S between each slot 119 and the adjacent slot(s) 119 of the first RDL pad 115a is less than 3 μm.

In another embodiment, the first device structure 100 further includes a first dielectric layer 111 over the first interconnect structure 105 and laterally surrounding the first RDL pad 115a, a second RDL pad 115b over the first interconnect structure 105 and electrically coupled to the metal features 107 of the first interconnect structure 105 by a second redistribution layer via 109b, the second RDL pad 115b including a metal material 114 laterally surrounded by the first dielectric layer 111, at least one bonding pad via 133 electrically connected to the upper surfaces 121, 122 of each of the first RDL pad 115a and the second RDL pad 115b, and the first RDL pad 115a has a width dimension along a first horizontal direction hd1 that is greater than a width dimension of the second RDL pad 115b along the first horizontal direction hd1.

In another embodiment, the structure further includes at least one passivation layer 123, 125 over upper surfaces 120, 121, 122 of the first dielectric layer 111, the first RDL pad 115a and the second RDL pad 115b, where bonding pad vias 133 extend through a portion of the dielectric material 129 of the first bonding layer 127 and the at least one passivation layer 123, 125 to electrically connect to the upper surfaces 121, 122 of the first RDL pad and the second RDL pad, and a difference in horizontal elevation of the upper surface of the first RDL pad and the upper surface of the second RDL pad at adjacent peripheral edges of the first RDL pad and the second RDL pad is 0.1 μm or less.

In another embodiment, multiple bonding pad vias 133 are electrically connected to the upper surface 121 of the first RDL pad 115a, and a single bonding pad via 133 is electrically connected to the upper surface 122 of the second RDL pad 115b, and a width dimension of the first redistribution layer via 109a is greater than a width dimension of the second redistribution layer via 109b.

In another embodiment, the structure further includes a third RDL pad 115c over the first interconnect structure 105, the third RDL pad 115c including a metal material 114 laterally surrounded by the first dielectric layer 111 and located between the first RDL pad 115a and the second RDL pad 115b, where the third RDL pad 115c is a non-functional dummy RDL pad 115c that does not electrically couple a bonding pad 131 of the first bonding layer 127 to underlying metal features 107 of the first interconnect structure 105.

Another embodiment is drawn to a bonded device structure 150 including a first device structure 100 including a first semiconductor substrate 101, first devices 103 disposed on or in a first side 102 of the first semiconductor substrate 101, a first interconnect structure 105 over the plurality of first devices 103 and the first side 102 of the first semiconductor substrate 101, the first interconnect structure 105 including metal features 107 within an interconnect dielectric material 106, and a first bonding layer 127 over the first interconnect structure 105, the first bonding layer 127 including a plurality of first bonding pads 131 surrounded by a bonding layer dielectric material 129, and a second device structure 200 including a second semiconductor substrate 201, second devices 203 disposed on or in a first side 202 of the second semiconductor substrate 201, a second interconnect structure 205 over the second devices 203 and the first side 202 of the second semiconductor substrate 201, the second interconnect structure 205 including metal features 207 within an interconnect dielectric material 206, and a second bonding layer 227 over the second interconnect structure 227, the second bonding layer 227 including a plurality of second bonding pads 231 surrounded by a bonding layer dielectric material 229, where the first bonding layer 127 is bonded to the second bonding layer 227 at a bonding interface 210 to electrically and mechanically couple the first device structure 100 to the second device structure 200, and where the first device structure 100 includes a plurality of redistribution layer pads (RDL) pads 115a, 115b, 115c and a first passivation layer 111 laterally surrounding each of the RDL pads 115a, 115b, 115c located between the first interconnect structure 105 and the first bonding layer 127, an etch stop layer 123 located between the plurality of RDL pads 115a, 115b, 115c and the first passivation layer 111 and the first bonding layer 127, and a second passivation layer 125 located between the etch stop layer 123 and the first bonding layer 127, where at least one of the RDL pads 115a, 115b provides an electrical pathway between a first bonding pad 131 of the first bonding layer 127 and a metal feature 107 of the first interconnect structure 105.

In one embodiment, the plurality of RDL pads includes a first RDL pad 115a and a second RDL pad 115b, where upper surfaces 121, 122 of the first RDL pad 115a and the second RDL pad 115b are electrically connected to bonding pad vias 133 electrically connecting the first RDL pad 115a and the second RDL pad 115b to respective first bonding pads 131 of the first bonding layer 127, and upper surfaces 121, 122 of the first RDL pad 115a and the second RDL pad 115b and an upper surface 120 of the first passivation layer 111 form a continuous flat surface.

In another embodiment, the plurality of RDL pads 115a, 115b, 115c include a dummy RDL pad 115c located between the first RDL pad 115a and the second RDL pad 115b, where the dummy RDL pad 115c does not provide an electrical pathway between a first bonding pad 131 of the first bonding layer 127 and a metal feature 107 of the first interconnect structure 105.

In another embodiment, a width dimension W1 of the upper surface of the dummy RDL pad 115c along a first horizontal direction hd1 is greater than a width dimension W2 of a lower surface of the dummy RDL pad 115c along the first horizontal direction hd1, the width dimension W1 of the upper surface of the dummy RDL pad 115 c along the first horizontal direction hd1 is at least 0.1 μm, and the width dimension W1 of the upper surface of the dummy RDL pad 115c along the first horizontal direction hd1 is less than width dimensions of the upper surfaces 121, 122 of the first RDL pad 115a and the second RDL pad 115b along the first horizonal direction hd1.

In another embodiment, the first RDL pad 115a includes at least one slot 119 including a dielectric material 118 laterally surrounded by a metal material 114.

Another embodiment is drawn to a method of fabricating a bonded device structure 150 that includes depositing a metal material 114 over a first redistribution structure 105 of a first device structure 100, forming a plurality of openings 117 in the metal material 114, depositing a dielectric material 118 over the metal material 114 and within the plurality of openings 117, performing a planarization process to remove portions of the dielectric material 118 and the metal material 114 and provide a redistribution layer (RDL) pad 115a including a plurality of slots 119 filled with the dielectric material 118 and laterally surrounded by the metal material 114, forming a first bonding layer 127 over the RDL pad 115a and a bonding pad via 133 extending between a bonding pad 131 of the first bonding layer 127 and an upper surface 121 of the RDL pad 115a, bonding the first bonding layer 127 of the first device structure 100 to a second bonding layer 227 of a second device structure 200 to bond the first device structure 100 to the second device structure 200.

In one embodiment, the method further includes forming at least one passivation layer 123, 125 over the RDL pad 115a, where the bonding layer 127 is formed over the at least one passivation layer 123, 125, and the bonding pad via 133 extends through the at least one passivation layer 123, 125 and contacts the upper surface 121 of the RDL pad 115a.

In another embodiment, the metal material 114 is deposited by electroplating, and performing the planarization process includes performing a chemical mechanical planarization process.

In another embodiment, the method further includes forming a first dielectric layer 111 over the first interconnect structure 105, and forming a first trench opening 113a and a second trench opening 113b in the first dielectric layer 111, where the metal material 114 is deposited within the first trench opening 113a and the second trench opening 113b, the plurality of openings 117 are formed by etching the metal material 114 through a patterned mask 116 to form the openings 117 within the metal material 114 located within the first trench opening 113a, and the planarization process provides a first RDL pad 115a including the plurality of slots 119 filled with the dielectric material 118 and laterally surrounded by the metal material 114 within the first trench opening 113a and a second RDL pad 115b including the metal material 114 within the second trench opening 113b.

In another embodiment, a third trench opening 113c is formed in the first dielectric layer 111 between the first trench opening 113a and the second trench opening 113b and the metal material 114 is deposited within the third trench opening 114, and the planarization process provides a third RDL pad 115c located between the first RDL pad 115a and the second RDL pad 115b, the first RDL pad 115a and the second RDL pad 115b provide an electrical pathway between respective bonding pads 131 of the first bonding layer 127 and underlying metal interconnect features 107 of the first interconnect structure 105 via bonding pad vias 133 contacting the upper surfaces 121, 122 of the first RDL pad 115a and the second RDL pad 115b, and the third RDL pad 115c is a dummy RDL pad 115c that does not provide an electrical pathway between the bonding pads 131 of the first bonding layer 127 and the underlying metal interconnect features 107 of the first interconnect structure 105.

The various embodiments disclosed herein may provide bonded die structures and methods of forming the same that provide reduced defects and higher reliability. A laser grooving process may be used to “precut” bonded device structures prior to a final dicing process. The laser grooving process may form relatively deep grooves in the bonded device structure that may extend beyond the bonding interface between a first device structure and a second device structure. A final dicing process along the precut grooves may be used to separate individual bonded die structures. Because the dicing occurs along the deep precut grooves that extend through the bonding interface between the stacked device structures, the dicing blade may not cut through or come into contact with the bonding interface. This may result in in reduced mechanical stress, which may decrease the occurrence of delamination defects between the device structures and thereby provide improved reliability and increased yields.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A structure, comprising:
a first device structure comprising:
a first semiconductor substrate;
first devices disposed on or in a first side of the first semiconductor substrate;
a first interconnect structure over the first devices and the first side of the first semiconductor substrate, the first interconnect structure comprising metal features within a dielectric material;
a first redistribution layer (RDL) pad over the first interconnect structure and electrically coupled to the metal features of the first interconnect structure by a first redistribution layer via, the first RDL pad comprising a metal material and a plurality of slots filled with dielectric material laterally surrounded by the metal material; and
a first bonding layer over the first RDL pad, the first bonding layer comprising a bonding pad laterally surrounded by a dielectric material, wherein a bonding pad via is electrically connected to the bonding pad of the first bonding layer and is electrically connected to an upper surface of the first RDL pad.

2. The structure of claim 1, further comprising:
a second device structure comprising:
a second semiconductor substrate;
second devices disposed on or in a first side of the second semiconductor substrate;
a second interconnect structure over the second devices and the first side of the second semiconductor substrate, the second interconnect structure comprising metal features within a dielectric material; and
a second bonding layer over the second interconnect structure, the second bonding layer comprising a bonding pad laterally surrounded by a dielectric material;
wherein the first bonding layer is bonded to the second bonding layer at a bonding interface to bond the first device structure to the second device structure.

3. The structure of claim 1, wherein each of the plurality of slots extend through an entire thickness of the first RDL pad.

4. The structure of claim 1, wherein the plurality of slots constitute between 20% and 25% of a total area of the upper surface of the first RDL pad.

5. The structure of claim 1, wherein a minimum spacing between each of the slots and a peripheral edge of the first RDL pad is at least 1 μm, and a minimum spacing between each bonding pad via that contacts the upper surface of the first RDL pad and each of the plurality of slots is at least 0.5 μm.

6. The structure of claim 1, wherein a minimum spacing between each of the plurality of slots and the adjacent slot of the first RDL pad is at least 1 μm, and a maximum spacing between each of the plurality of slots and the adjacent slot of the first RDL pad is less than 3 μm.

7. The structure of claim 1, wherein the first device structure further comprises:
a first dielectric layer over the first interconnect structure and laterally surrounding the first RDL pad; and
a second RDL pad over the first interconnect structure and electrically coupled to the metal features of the first interconnect structure by a second redistribution layer via, the second RDL pad comprising a metal material laterally surrounded by the first dielectric layer, at least one bonding pad via is electrically connected to the upper surfaces of each of the first RDL pad and the second RDL pad, and the first RDL pad has a width dimension along a first horizontal direction that is greater than a width dimension of the second RDL pad along the first horizontal direction.

8. The structure of claim 7, further comprising:
at least one passivation layer over upper surfaces of the first dielectric layer, the first RDL pad and the second RDL pad, wherein bonding pad vias extend through a portion of the dielectric material of the first bonding layer and the at least one passivation layer to electrically connect to the upper surfaces of the first RDL pad and the second RDL pad, and a difference in horizontal elevation of the upper surface of the first RDL pad and the upper surface of the second RDL pad at adjacent peripheral edges of the first RDL pad and the second RDL pad is 0.1 μm or less.

9. The structure of claim 8, wherein multiple bonding pad vias are electrically connected to the upper surface of the first RDL pad, and a single bonding pad via is electrically connected to the upper surface of the second RDL pad, and a width dimension of the first redistribution layer via is greater than a width dimension of the second redistribution layer via.

10. The structure of claim 7, further comprising:
a third RDL pad over the first interconnect structure, the third RDL pad comprising a metal material laterally surrounded by the first dielectric layer and located between the first RDL pad and the second RDL pad, wherein the third RDL pad is a non-functional dummy RDL pad that does not electrically couple a bonding pad of the first bonding layer to underlying metal features of the first interconnect structure.

11. A bonded device structure, comprising:
a first device structure comprising:
a first semiconductor substrate;
first devices disposed on or in a first side of the first semiconductor substrate;
a first interconnect structure over the plurality of first devices and the first side of the first semiconductor substrate, the first interconnect structure comprising metal features within an interconnect dielectric material; and
a first bonding layer over the first interconnect structure, the first bonding layer comprising a plurality of first bonding pads laterally surrounded by a bonding layer dielectric material; and
a second device structure comprising:
a second semiconductor substrate;
second devices disposed on, or in a first side of the second semiconductor substrate;
a second interconnect structure over the second devices and the first side of the second semiconductor substrate, the second interconnect structure comprising metal features within an interconnect dielectric material; and
a second bonding layer over the second interconnect structure, the second bonding layer comprising a plurality of second bonding pads surrounded by a bonding layer dielectric material;
wherein the first bonding layer is bonded to the second bonding layer at a bonding interface to electrically and mechanically couple the first device structure to the second device structure, and wherein;
the first device structure comprises a plurality of redistribution layer (RDL) pads and a first passivation layer laterally surrounding each of the RDL pads located between the first interconnect structure and the first bonding layer, an etch stop layer located between the plurality of RDL pads and the first passivation layer and the first bonding layer, and a second passivation layer located between the etch stop layer and the first bonding layer, wherein at least one of the RDL pads provides an electrical pathway between a first bonding pad of the first bonding layer and a metal feature of the first interconnect structure.

12. The bonded device structure of claim 11, wherein the plurality of RDL pads comprises a first RDL pad and a second RDL pad, wherein upper surfaces of the first RDL pad and the second RDL pad are electrically connected to bonding pad vias electrically connecting the first RDL pad and the second RDL pad to respective first bonding pads of the first bonding layer, and the upper surfaces of the first RDL pad and the second RDL pad and an upper surface of the first passivation layer form a continuous flat surface.

13. The bonded device structure of 12, wherein the plurality of RDL pads comprise a dummy RDL pad located between the first RDL pad and the second RDL pad, wherein the dummy RDL pad does not provide an electrical pathway between a first bonding pad of the first bonding layer and a metal feature of the first interconnect structure.

14. The bonded device structure of claim 13, wherein a width dimension of the upper surface of the dummy RDL pad along a first horizontal direction is greater than a width dimension of a lower surface of the dummy RDL pad along the first horizontal direction, the width dimension of the upper surface of the dummy RDL pad along the first horizontal direction is at least 0.1 μm, and the width dimension of the upper surface of the dummy RDL pad along the first horizontal direction is less than width dimensions of the upper surfaces of the first RDL pad and the second RDL pad along the first horizonal direction.

15. The bonded device structure of claim 12, wherein the first RDL pad comprises at least one slot comprising a dielectric material laterally surrounded by a metal material.

16. A method of fabricating a bonded device structure, comprising:
depositing a metal material over a first redistribution structure of a first device structure;
forming a plurality of openings in the metal material;
depositing a dielectric material over the metal material and within the plurality of openings;
performing a planarization process to remove portions of the dielectric material and the metal material and provide a redistribution layer (RDL) pad comprising a plurality of slots filled with the dielectric material and laterally surrounded by the metal material;
forming a first bonding layer over the RDL pad and a bonding pad via extending between a bonding pad of the first bonding layer and an upper surface of the RDL pad; and
bonding the first bonding layer of the first device structure to a second bonding layer of a second device structure to bond the first device structure to the second device structure.

17. The method of claim 16, further comprising:
forming at least one passivation layer over the RDL pad, wherein the first bonding layer is formed over the at least one passivation layer, and the bonding pad via extends through the at least one passivation layer and contacts the upper surface of the RDL pad.

18. The method of claim 16, wherein the metal material is deposited by electroplating, and performing the planarization process comprises performing a chemical mechanical planarization process.

19. The method of claim 16, further comprising:
forming a first dielectric layer over a first interconnect structure; and
forming a first trench opening and a second trench opening in the first dielectric layer, wherein:
the metal material is deposited within the first trench opening and the second trench opening;
the plurality of openings are formed by etching the metal material through a patterned mask to form the each of the plurality of openings within the metal material located within the first trench opening; and
the planarization process provides a first RDL pad comprising the plurality of slots filled with the dielectric material and laterally surrounded by the metal material within the first trench opening and a second RDL pad comprising the metal material within the second trench opening.

20. The method of claim 19, wherein:
a third trench opening is formed in the first dielectric layer between the first trench opening and the second trench opening and the metal material is deposited within the third trench opening, and the planarization process provides a third RDL pad located between the first RDL pad and the second RDL pad;
the first RDL pad and the second RDL pad provide an electrical pathway between respective bonding pads of the first bonding layer and underlying metal interconnect features of the first interconnect structure via bonding pad vias contacting the upper surfaces of the first RDL pad and the second RDL pad; and
the third RDL pad comprises a dummy RDL pad that does not provide an electrical pathway between the bonding pads of the first bonding layer and the underlying metal interconnect features of the first interconnect structure.
